(19) United States
(12) Patent Application Publication
(10) Pub. No.: US 2024/0268188 A1
(43) Pub. Date: Aug. 8, 2024

(54) DISPLAY DEVICE AND MANUFACTURING METHOD THEREOF

(71) Applicant: Japan Display Inc., Tokyo (JP)

(72) Inventors: So NISHIYAMA, Tokyo (JP); Sho YANAGISAWA, Tokyo (JP)

(73) Assignee: Japan Display Inc., Tokyo (JP)

(21) Appl. No.: 18/418,385

(22) Filed: Jan. 22, 2024

(30) Foreign Application Priority Data
Feb. 3, 2023 (JP) 2023-015173

(51) Int. Cl. H10K 59/82; H10K 59/80; H10K 71/20; H10K 71/60

(52) U.S. Cl. CPC H10K 59/82; H10K 59/80521; H10K 59/871; H10K 71/233; H10K 71/60

(57) ABSTRACT

According to one embodiment, a manufacturing method of a display device includes forming an inorganic insulating layer which covers a lower electrode, a feed terminal and a mounting terminal, forming a first aperture from which the feed terminal is exposed in the inorganic insulating layer, forming a partition which is in contact with the feed terminal through the first aperture, forming a second aperture from which the lower electrode is exposed in the inorganic insulating layer, forming an organic layer which is in contact with the lower electrode through the second aperture, and forming an upper electrode which covers the organic layer.

### CROSS-REFERENCE TO RELATED APPLICATIONS

This application is based upon and claims the benefit of priority from Japanese Patent Application No. 2023-015173, filed Feb. 3, 2023, the entire contents of which are incorporated herein by reference.

### FIELD

Embodiments described herein relate generally to a display device and a manufacturing method thereof.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

In the process of manufacturing such a display element, a technique which improves the manufacturing yield is required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is a schematic cross-sectional view of the display device DSP along the A-B line of FIG. 2.

FIG. 4 is a cross-sectional view showing a feed portion PP.

FIG. 5 is a cross-sectional view showing a mounting portion MP.

FIG. 6 is a cross-sectional view showing an inspection portion TP.

FIG. 7 is a diagram for explaining the manufacturing method of the display device DSP.

FIG. 8 is a diagram for explaining the manufacturing method of the display device DSP.

FIG. 9 is a diagram for explaining the manufacturing method of the display device DSP.

FIG. 10 is a diagram for explaining the manufacturing method of the display device DSP.

FIG. 11 is a diagram for explaining the manufacturing method of the display device DSP.

FIG. 12 is a diagram for explaining the manufacturing method of the display device DSP.

FIG. 13 is a diagram for explaining the manufacturing method of the display device DSP.

FIG. 14 is a diagram for explaining the manufacturing method of the display device DSP.

FIG. 15 is a diagram for explaining the manufacturing method of the display device DSP.

FIG. 16 is a diagram for explaining step ST11 of a first manufacturing method.

FIG. 17 is a diagram for explaining step ST12 of the first manufacturing method.

FIG. 18 is a diagram for explaining step ST13 of the first manufacturing method.

FIG. 19 is a diagram for explaining step ST14 of the first manufacturing method.

FIG. 20 shows a state in which a material CD for forming a partition 6 partly remains in the mounting portion MP and the inspection portion TP in step ST13 shown in FIG. 18.

FIG. 21 is a diagram for explaining step ST21 of a second manufacturing method.

FIG. 22 is a diagram for explaining step ST22 of the second manufacturing method.

FIG. 23 is a diagram for explaining step ST31 of a third manufacturing method.

FIG. 24 is a diagram for explaining step ST32 of the third manufacturing method.

### DETAILED DESCRIPTION

Embodiments aim to provide a display device in which the manufacturing yield can be improved and a manufacturing method thereof.

In general, according to one embodiment, a manufacturing method of a display device comprises forming an inorganic insulating layer which covers a lower electrode located in a display area, a feed terminal located in a surrounding area outside the display area, and a mounting terminal for mounting a signal source, forming a first aperture from which the feed terminal is exposed in the inorganic insulating layer by performing etching using a first resist formed on the inorganic insulating layer as a mask, forming a partition comprising a conductive lower portion which is located on the inorganic insulating layer in the display area and is in contact with the feed terminal through the first aperture in the surrounding area and an upper portion which is located on the lower portion and protrudes from a side surface of the lower portion after removing the first resist, forming a second aperture from which the lower electrode is exposed in the inorganic insulating layer by performing etching using a second resist formed on the inorganic insulating layer and the partition as a mask, forming an organic layer which is in contact with the lower electrode through the second aperture by depositing a first material using the partition as a mask after removing the second resist, and forming an upper electrode which covers the organic layer and is in contact with the lower portion of the partition by depositing a second material using the partition as a mask.

According to another embodiment, a display device comprises a substrate, an organic insulating layer provided over a display area and a surrounding area outside the display area above the substrate, a lower electrode provided on the organic insulating layer in the display area, a feed terminal provided on the organic insulating layer in the surrounding area, a mounting terminal exposed from a first through hole of the organic insulating layer in the surrounding area, an inorganic insulating layer provided over the display area and the surrounding area on the organic insulating layer, and comprising a first aperture from which the feed terminal is exposed, a second aperture from which the lower electrode is exposed, and a third aperture from which the mounting terminal is exposed, a partition comprising a conductive lower portion which is provided on the inorganic insulating layer and is in contact with the feed terminal through the first aperture, and an upper portion which is provided on the lower portion and protrudes from a side surface of the lower portion, an organic layer which is in contact with the lower electrode through the second aperture, and an upper electrode which covers the organic layer and is in contact with the lower portion of the partition.

According to yet another embodiment, a display device comprises a substrate, an organic insulating layer provided over a display area and a surrounding area outside the display area above the substrate, a lower electrode provided on the organic insulating layer in the display area, a feed terminal provided on the organic insulating layer in the surrounding area, an inorganic insulating layer provided over the display area and the surrounding area on the organic insulating layer and comprising a first aperture from which the feed terminal is exposed and a second aperture from which the lower electrode is exposed, a partition comprising a conductive lower portion which is provided on the inorganic insulating layer and is in contact with the feed terminal through the first aperture and an upper portion which is provided on the lower portion and protrudes from a side surface of the lower portion, an organic layer which is in contact with the lower electrode through the second aperture, and an upper electrode which is provided on the organic layer and is in contact with the lower portion of the partition.

The embodiments can provide a display device in which the manufacturing yield can be improved and a manufacturing method thereof.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view. When terms indicating the positional relationships of two or more structural elements, such as “on”, “above” “between” and “face”, are used, the target structural elements may be directly in contact with each other or may be spaced apart from each other as a gap or another structural element is interposed between them. The positive direction of the Z-axis is referred to as “on” or “above”.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

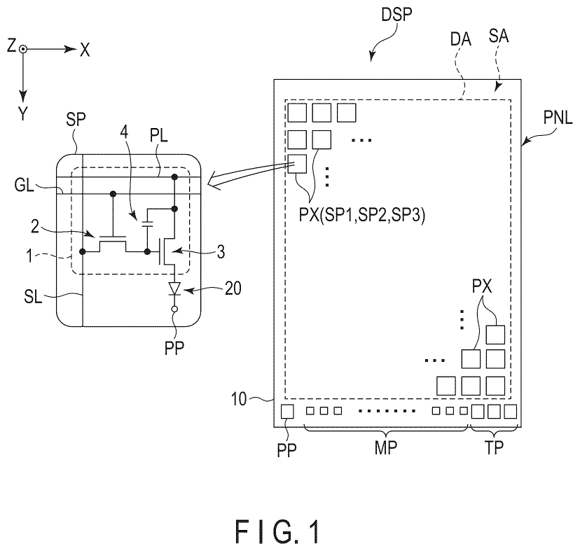

FIG. 1 is a diagram showing a configuration example of a display device DSP.

The display device DSP comprises a display panel PNL comprising a display area DA which displays an image and a surrounding area SA located on an external side relative to the display area DA on an insulating substrate 10. The substrate 10 may be glass or a resinous film having flexibility.

In the embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3. It should be noted that the combination of subpixels is not limited to three elements. The combination may consist of two elements or may consist of four or more elements by adding subpixel SP4, etc., to subpixels SP1 to SP3.

Each subpixel SP comprises a pixel circuit 1 and a display element 20 driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element 20.

It should be noted that the configuration of the pixel circuit 1 is not limited to the example shown in the figure. For example, the pixel circuit 1 may 1 may comprise more thin-film transistors and capacitors.

The display element 20 is an organic light emitting diode (OLED) as a light emitting element, and may be called an organic EL element.

The surrounding area SA comprises a feed portion PP, a mounting portion MP and an inspection portion TP.

The feed portion PP comprises a feed terminal electrically connected to the cathode of the display element 20.

The mounting portion MP comprises a mounting terminal for connecting signal sources such as an IC chip and a flexible printed circuit board.

The inspection portion TP comprises an inspection terminal for connecting an inspection probe.

The details of the feed terminal, the mounting terminal and the inspection terminal are described later.

It should be noted that the inspection portion TP may be omitted.

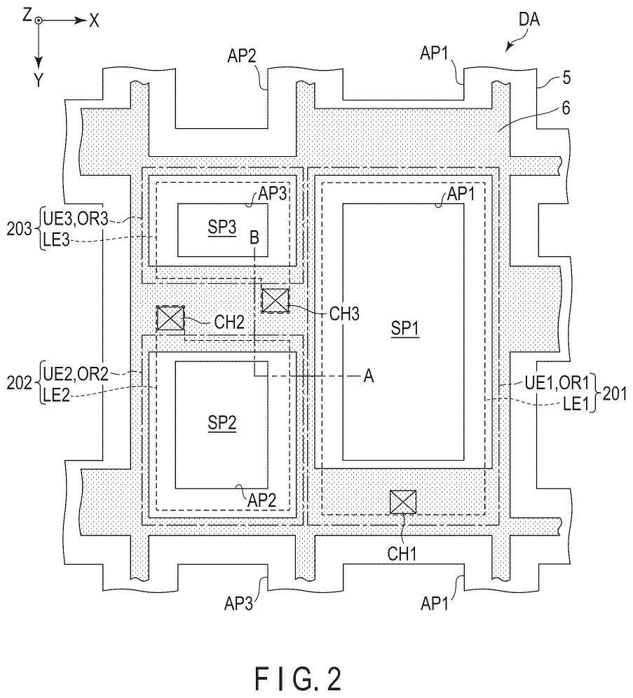

FIG. 2 is a diagram showing an example of the layout of subpixels SP1, SP2 and SP3.

In the example of FIG. 2, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, in the display area DA, a column in which subpixels SP2 and SP3 are alternately provided in the second direction Y and a column in which a plurality of subpixels SP1 are provided in the second direction Y are formed. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

An inorganic insulating layer 5 and a partition 6 are provided in the display area DA. The inorganic insulating layer 5 comprises apertures AP1, AP2 and AP3 in subpixels SP1, SP2 and SP3, respectively.

The partition 6 overlaps the inorganic insulating layer 5 as seen in plan view. The partition 6 is formed into a grating shape surrounding the apertures AP1, AP2 and AP3. In other words, the partition 6 comprises apertures in subpixels SP1, SP2 and SP3 in a manner similar to that of the inorganic insulating layer 5.

Subpixels SP1, SP2 and SP3 comprise display elements 201, 202 and 203, respectively, as the display elements 20.

The display element 201 of subpixel SP1 comprises a lower electrode LE1, an upper electrode UE1 and an organic layer OR1 overlapping the aperture AP1. The peripheral portion of the lower electrode LE1 is covered with the inorganic insulating layer 5. The organic layer OR1 and the upper electrode UE1 are surrounded by the partition 6. The peripheral portion of each of the organic layer OR1 and the upper electrode UE1 overlaps the inorganic insulating layer 5 as seen in plan view. The organic layer OR1 includes a light emitting layer which emits light in, for example, a blue wavelength range.

The display element 202 of subpixel SP2 comprises a lower electrode LE2, an upper electrode UE2 and an organic layer OR2 overlapping the aperture AP2. The peripheral portion of the lower electrode LE2 is covered with the inorganic insulating layer 5. The organic layer OR2 and the upper electrode UE2 are surrounded by the partition 6. The peripheral portion of each of the organic layer OR2 and the upper electrode UE2 overlaps the inorganic insulating layer 5 as seen in plan view. The organic layer OR2 includes a light emitting layer which emits light in, for example, a green wavelength range.

The display element 203 of subpixel SP3 comprises a lower electrode LE3, an upper electrode UE3 and an organic layer OR3 overlapping the aperture AP3. The peripheral portion of the lower electrode LE3 is covered with the inorganic insulating layer 5. The organic layer OR3 and the upper electrode UE3 are surrounded by the partition 6. The peripheral portion of each of the organic layer OR3 and the upper electrode UE3 overlaps the inorganic insulating layer 5 5 as seen in plan view. The organic layer OR3 includes a light emitting layer which emits light in, for example, a red wavelength range.

In the example of FIG. 2, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. It should be noted that the outer shape of each of the lower electrodes, organic layers or upper electrodes shown in the figure does not necessarily reflect the accurate shape.

The lower electrodes LE1, LE2 and LE3 correspond to, for example, the anodes of the display elements. The upper electrodes UE1, UE2 and UE3 correspond to the cathodes of the display elements or a common electrode.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

In the example of FIG. 2, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

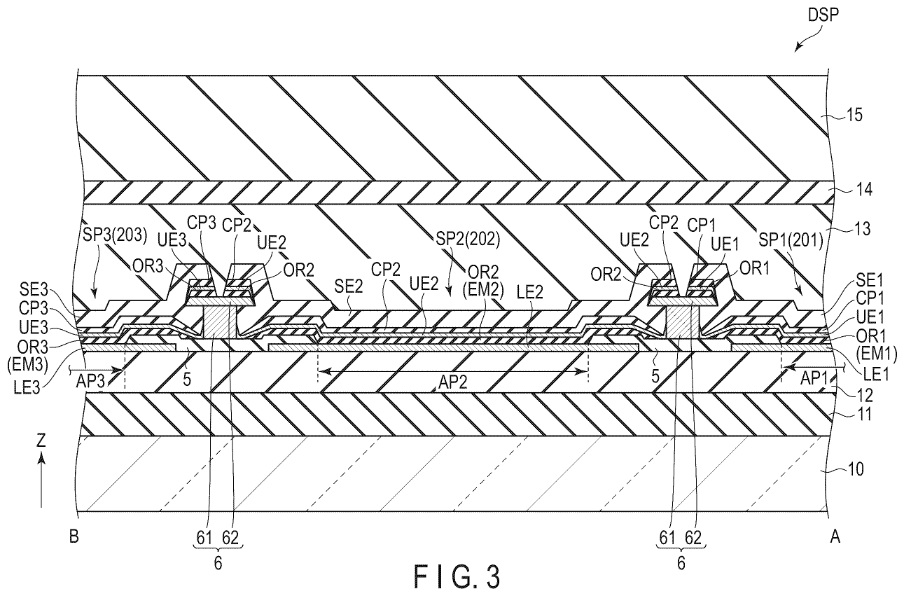

FIG. 3 is a schematic cross-sectional view of the display device DSP along the A-B line of FIG. 2.

A circuit layer 11 is provided on the substrate 10. The circuit layer 11 includes various circuits such as the pixel circuit 1 shown in FIG. 1 and various lines such as the scanning line GL, the signal line SL and the power line PL. The circuit layer 11 is covered with an organic insulating layer 12. The organic insulating layer 12 planarizes the irregularities formed by the circuit layer 11.

The lower electrodes LE1, LE2 and LE3 are provided on the organic insulating layer 12 and are spaced apart from each other. The inorganic insulating layer 5 is provided on the organic insulating layer 12 and the lower electrodes LE1, LE2 and LE3. The aperture AP1 of the inorganic insulating layer 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the inorganic insulating layer 5. The organic insulating layer 12 is covered with the inorganic insulating layer 5 between, of the lower electrodes LE1, LE2 and LE3, the lower electrodes which are adjacent to each other. The lower electrodes LE1, LE2 and LE3 are connected to the pixel circuits 1 of subpixels SP1, SP2 and SP3, respectively, through the contact holes provided in the organic insulating layer 12. It should be noted that, although the contact holes of the organic insulating layer 12 are omitted in FIG. 3, the contact holes correspond to the contact holes CH1, CH2 and HC3 of FIG. 2.

The partition 6 includes a conductive lower portion (stem) 61 provided on the inorganic insulating layer 5 and an upper portion (cap) 62 provided on the lower portion 61. The lower portion 61 of the partition 6 shown on the right side of the figure is located between the aperture AP1 and the aperture AP2. The lower portion 61 of the partition 6 shown on the left side of the figure is located between the aperture AP2 and the aperture AP3. The upper portion 62 has a width greater than that of the lower portion 61. The both end portions of the upper portion 62 protrude relative to the side surfaces of the lower portion 61. This shape of the partition 6 is called an overhang shape.

The organic layer OR1 is in contact with the lower electrode LE1 through the aperture AP1 and covers the lower electrode LE1 exposed from the aperture AP1. The peripheral portion of the organic layer OR1 is located on the inorganic insulating layer 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the inorganic insulating layer 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the inorganic insulating layer 5. The upper electrode UE3 covers the organic layer OR3 and is in contact with the lower portion 61.

In the example of FIG. 3, subpixel SP1 comprises a cap layer CP1 and a sealing layer SE1. Subpixel SP2 comprises a cap layer CP2 and a sealing layer SE2. Subpixel SP3 comprises a cap layer CP3 and a sealing layer SE3. The cap layers CP1, CP2 and CP3 function as optical adjustment layers which improve the extraction efficiency of the light emitted from the organic layers OR1, OR2 and OR3, respectively.

The cap layer CP1 is provided on the upper electrode UE1.

The cap layer CP2 is provided on the upper electrode UE2.

The cap layer CP3 is provided on the upper electrode UE3.

The sealing layer SE1 is provided on the cap layer CP1, is in contact with the partition 6 and continuously covers each member of subpixel SP1.

The sealing layer SE2 is provided on the cap layer CP2, is in contact with the partition 6 and continuously covers each member of subpixel SP2.

The sealing layer SE3 is provided on the cap layer CP3, is in contact with the partition 6 and continuously covers each member of subpixel SP3.

In the example of FIG. 3, each of the organic layer OR1, the upper electrode UE1 and the cap layer CP1 is partly located on the partition 6 around subpixel SP1. These portions are spaced apart from, of the organic layer OR1, the upper electrode UE1 and the cap layer CP1, the portions located in the aperture AP1 (the portions constituting the display element 201).

Similarly, each of the organic layer OR2, the upper electrode UE2 and the cap layer CP2 is partly located on the partition 6 around subpixel SP2. These portions are spaced apart from, of the organic layer OR2, the upper electrode UE2 and the cap layer CP2, the portions located in the aperture AP2 (the portions constituting the display element 202).

Similarly, each of the organic layer OR3, the upper electrode UE3 and the cap layer CP3 is partly located on the partition 6 around subpixel SP3. These portions are spaced apart from, of the organic layer OR3, the upper electrode UE3 and the cap layer CP3, the portions located in the aperture AP3 (the portions constituting the display element 203).

The end portions of the sealing layers SE1, SE2 and SE3 are located above the partition 6. In the example of FIG. 3, the end portions of the sealing layers SE1 and SE2 located above the partition 6 between subpixels SP1 and SP2 are spaced apart from each other. The end portions of the sealing layers SE2 and SE3 located above the partition 6 between subpixels SP2 and SP3 are spaced apart from each other.

The sealing layers SE1, SE2 and SE3 are covered with a resin layer 13. The resin layer 13 is covered with a sealing layer 14. The sealing layer 14 is covered with a resin layer 15.

The inorganic insulating layer 5 is formed of, for example, an inorganic insulating material such as silicon nitride (SiNx), silicon oxide (SiOx), silicon oxynitride (SiON) or aluminum oxide (Al₂O₃).

Each of the sealing layers SE1, SE2 and SE3 and the sealing layer 14 is formed of, for example, silicon nitride (SiNx). Each of the sealing layers SE1, SE2 and SE3 and the sealing layer 14 may be formed of another inorganic insulating material such as silicon oxide (SiOx), silicon oxynitride (SiON) or aluminum oxide (Al₂O₃).

For example, the inorganic insulating layer 5 is formed of a material which is different from the materials of the sealing layers SE1, SE2 and SE3. It should be noted that there is a possibility that the inorganic insulating layer 5 is formed of the same material as the sealing layers SE1, SE2 and SE3.

The lower portion 61 of the partition 6 is formed of a conductive material and is electrically connected to the upper electrodes UE1, UE2 and UE3. The upper portion 62 of the partition 6 is formed of, for example, a conductive material. However, the upper portion 62 may be formed of an insulating material. The lower portion 61 is formed of a material which is different from that of the upper portion 62.

For example, each of the lower electrodes LE1, LE2 and LE3 is a multilayer body including a transparent electrode formed of an oxide conductive material such as indium tin oxide (ITO) and a metal electrode formed of a metal material such as silver.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other. It should be noted that at least one of the cap layers CP1, CP2 and CP3 may be omitted.

The circuit layer 11, organic insulating layer 12 and inorganic insulating layer 5 shown in FIG. 3 are provided over the display area DA and the surrounding area SA. The partition 6 extends from the display area DA to the surrounding area SA.

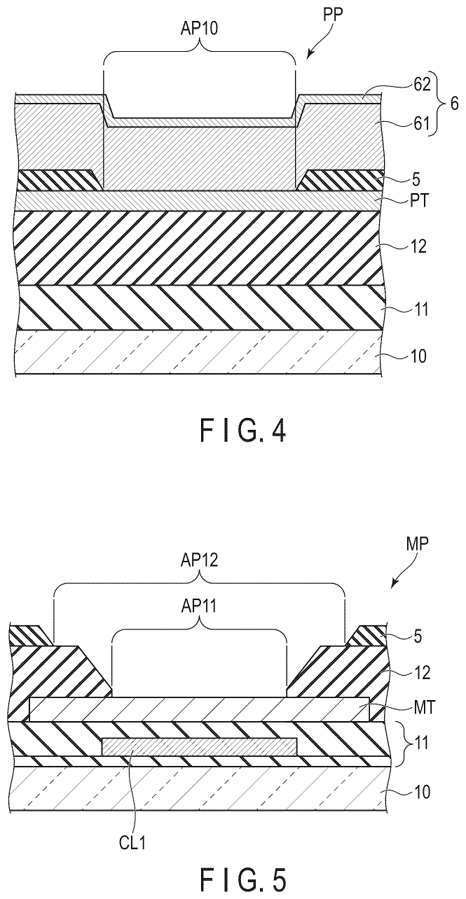

FIG. 4 is a cross-sectional view showing the feed portion PP.

The feed portion PP is provided in the surrounding area SA as shown in FIG. 1.

The feed portion PP comprises a feed terminal PT. The feed terminal PT is provided on the organic insulating layer 12. The feed terminal PT is a terminal for supplying common voltage to the cathodes (upper electrodes) of the display elements. The feed terminal PT is formed of, for example, the same material as the lower electrodes LE1, LE2 and LE3 shown in FIG. 3. The peripheral portions of the feed terminal PT are covered with the inorganic insulating layer 5.

The inorganic insulating layer 5 comprises an aperture AP10 from which the feed terminal PT is exposed.

The partition 6 is provided on the inorganic insulating layer 5 and extends to the feed portion PP.

In the feed portion PP, the lower portion 61 of the partition 6 is in contact with the feed terminal PT through the aperture AP10. By this configuration, the upper electrodes UE1, UE2 and UE3 of the display area DA are electrically connected to the feed terminal PT through the partition 6. Common voltage is applied to the upper electrodes UE1, UE2 and UE3 from the feed terminal PT.

FIG. 5 is a cross-sectional view showing the mounting portion MP.

The mounting portion MP is provided in the surrounding area SA as shown in FIG. 1.

The mounting portion MP comprises a mounting terminal MT. The mounting terminal MT is provided on an insulating layer included in the circuit layer 11. The mounting terminal MT is formed of, for example, a metal material which is different from the materials of the lower electrodes LE1, LE2 and LE3 shown in FIG. 3. For example, the mounting terminal MT is formed of a stacked layer body consisting of a molybdenum layer and an aluminum layer, or a stacked layer body consisting of a titanium layer and an aluminum layer. The peripheral portions of the mounting terminal MT are covered with the organic insulating layer 12.

The organic insulating layer 12 comprises an aperture AP11 from which the mounting terminal MT is exposed.

The inorganic insulating layer 5 is provided on the organic insulating layer 12 and comprises an aperture AP12 from which the mounting terminal MT is exposed. The aperture AP12 overlaps the aperture AP11. The organic insulating layer 12 which surrounds the aperture AP11 is exposed from the aperture AP12.

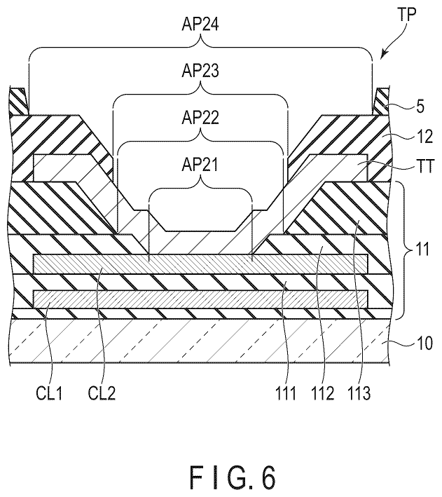

FIG. 6 is a cross-sectional view showing the inspection portion TP.

The inspection portion TP is provided in the surrounding area SA as shown in FIG. 1.

The circuit layer 11 comprises conductive layers CL1 and CL2, inorganic insulating layers 111 and 112 and an organic insulating layer 113.

The conductive layer CL1 is a conductive layer forming the scanning line GL shown in FIG. 1 and is provided above the substrate 10. The conductive layer CL1 is formed of, for example, an alloy of molybdenum and tungsten. The inorganic insulating layer 111 covers the conductive layer CL1.

The conductive layer CL2 is a conductive layer forming the signal line SL shown in FIG. 1 and is provided on the inorganic insulating layer 111. For example, the conductive layer CL2 is formed of a stacked layer body consisting of a molybdenum layer and an aluminum layer, or a stacked layer body consisting of a titanium layer and an aluminum layer. The inorganic insulating layer 112 is provided on the inorganic insulating layer 111 and covers the peripheral portion of the conductive layer CL2. The inorganic insulating layer 112 comprises an aperture AP21 from which the conductive layer CL2 is exposed. The organic insulating layer 113 is provided on the inorganic insulating layer 112 and comprises an aperture AP22 from which the conductive layer CL2 is exposed.

The inspection portion TP comprises an inspection terminal TT. The inspection terminal TT is provided on the organic insulating layer 113 and is in contact with the conductive layer CL2 through the aperture AP22. For example, the inspection terminal TT is formed of a metal material which is different from the materials of the lower electrodes LE1, LE2 and LE3 shown in FIG. 3 and is formed of the same material as the mounting material MT shown in FIG. 5. For example, the inspection terminal TT is formed of a stacked layer body consisting of a molybdenum layer and an aluminum layer, or a stacked layer body consisting of a titanium layer and an aluminum layer. The peripheral portions of the inspection terminal TT are covered with the organic insulating layer 12.

The organic insulating layer 12 comprises an aperture AP23 from which the inspection terminal TT is exposed.

The inorganic insulating layer 5 is provided on the organic insulating layer 12 and comprises an aperture AP24 from which the inspection terminal TT is exposed. The aperture AP24 overlaps the aperture AP23. The organic insulating layer 12 which surrounds the aperture AP23 is exposed from the aperture AP24.

In this specification, for example, the aperture AP10 of the inorganic insulating layer 5 formed in the feed portion PP corresponds to a first aperture. Each of the apertures AP1, AP2 and AP3 of the inorganic insulating layer 5 formed in the display area DA correspond to a second aperture. The aperture AP12 of the inorganic insulating layer 5 formed in the mounting portion MP corresponds to a third aperture. The aperture AP24 of the inorganic insulating layer 5 formed in the inspection portion TP corresponds to a fourth aperture. The aperture AP11 of the organic insulating layer 12 formed in the mounting portion MP corresponds to a first through hole. The aperture AP23 of the organic insulating layer 12 formed in the inspection portion TP corresponds to a second through hole.

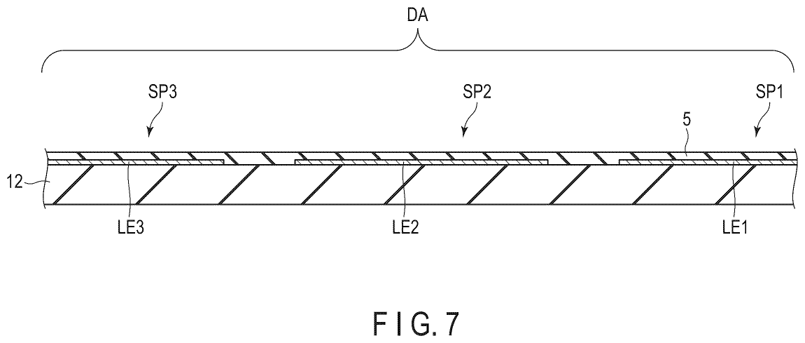

Now, this specification explains the manufacturing method of the display device DSP with reference to FIG. 7 to FIG. 15. In FIG. 7 to FIG. 15, the illustration of the lower side of the organic insulating layer 12 is omitted.

First, as shown in FIG. 7, the lower electrode LE1 of subpixel SP1, the lower electrode LE2 of subpixel SP2 and the lower electrode LE3 of subpixel SP3 are formed on the organic insulating layer 12.

Subsequently, the inorganic insulating layer 5 which covers the lower electrodes LE1, LE2 and LE3 is formed by depositing an inorganic insulating material. Here, to the inorganic insulating material, for example, silicon oxynitride (SiON) is applied. The inorganic insulating layer 5 is formed by, for example, chemical vapor deposition (CVD). The inorganic insulating layer 5 is formed in the surrounding area SA in addition to the display area DA.

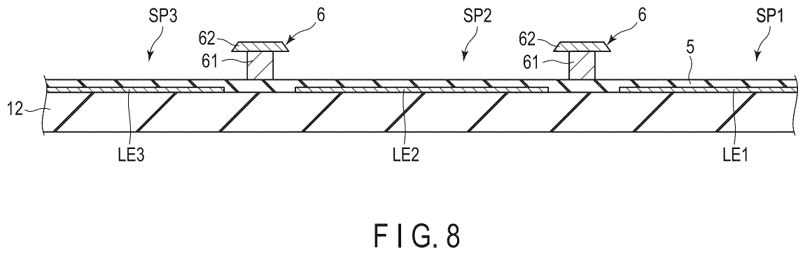

Subsequently, as shown in FIG. 8, the partition 6 which comprises the lower portion 61 located on the inorganic insulating layer 5 and formed of a conductive material and the upper portion 62 located on the lower portion 61 and protruding from the side surfaces of the lower portion 61 is formed.

In the process of forming the partition 6, first, a first layer including a conductive layer is formed on the inorganic insulating layer 5. Subsequently, a second layer is formed on the first layer. The conductive layer of the first layer is formed of a conductive material such as aluminum. The second layer may be formed of a conductive material or may be formed of an insulating material.

Subsequently, the second layer and the first layer are patterned in order by performing etching using a resist located on the second layer and having a predetermined shape as a mask. By this process, the partition 6 is formed. The lower portion 61 of the partition 6 is formed by patterning the first layer. The upper portion 62 is formed by patterning the second layer.

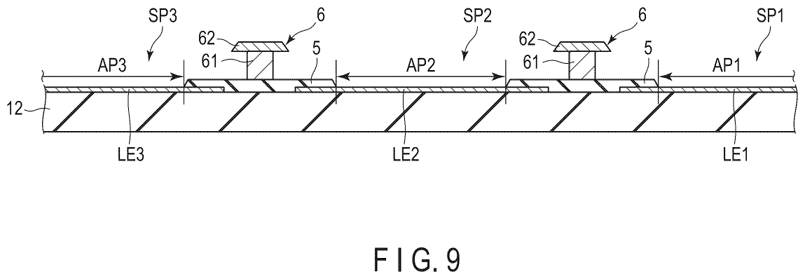

Subsequently, as shown in FIG. 9, the aperture AP1 from which the lower electrode LE1 is exposed, the aperture AP2 from which the lower electrode LE2 is exposed and the aperture AP3 from which the lower electrode LE3 is exposed are formed by patterning the inorganic insulating layer 5.

Subsequently, the display element 201 is formed.

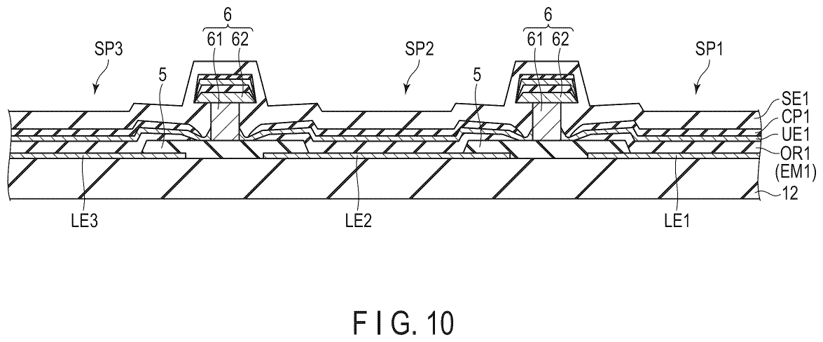

First, as shown in FIG. 10, the organic layer OR1 is formed by depositing the materials for forming the hole injection layer, the hole transport layer, the electron blocking layer, the light emitting layer (EM1), the hole blocking layer, the electron transport layer, the electron injection layer, etc., on the lower electrode LE1 in series using the partition 6 as a mask.

Subsequently, the upper electrode UE1 is formed by depositing a mixture of magnesium and silver on the organic layer OR1 using the partition 6 as a mask. The upper electrode UE1 covers the organic layer OR1 and is in contact with the side surface of the lower portion 61.

Subsequently, the cap layer CP1 is formed by depositing a high-refractive material and a low-refractive material in order on the upper electrode UE1 using the partition 6 as a mask.

Subsequently, the sealing layer SE1 is formed so as to continuously cover the cap layer CP1 and the partition 6.

The organic layer OR1, the upper electrode UE1, the cap layer CP1 and the sealing layer SE1 are formed in at least the entire display area DA and are provided in subpixels SP2 and SP3 as well as subpixel SP1. The organic layer OR1, the upper electrode UE1 and the cap layer CP1 are divided by the partition 6 having an overhang shape.

The materials which are emitted from an evaporation source when the organic layer OR1, the upper electrode UE1 and the cap layer CP1 are formed by vapor deposition are blocked by the upper portion 62. Thus, each of the organic layer OR1, the upper electrode UE1 and the cap layer CP1 is partly stacked on the upper portion 62. The organic layer OR1, upper electrode UE1 and cap layer CP1 located on the upper portion 62 are spaced apart from the organic layer OR1, upper electrode UE1 and cap layer CP1 located immediately above the lower electrode LE1.

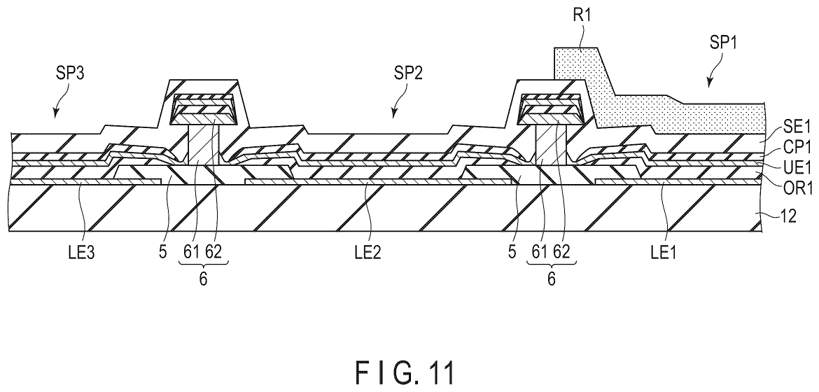

Subsequently, as shown in FIG. 11, a resist R1 having a predetermined shape is formed on the sealing layer SE1. The resist R1 overlaps subpixel SP1 and part of the partition 6 around subpixel SP1.

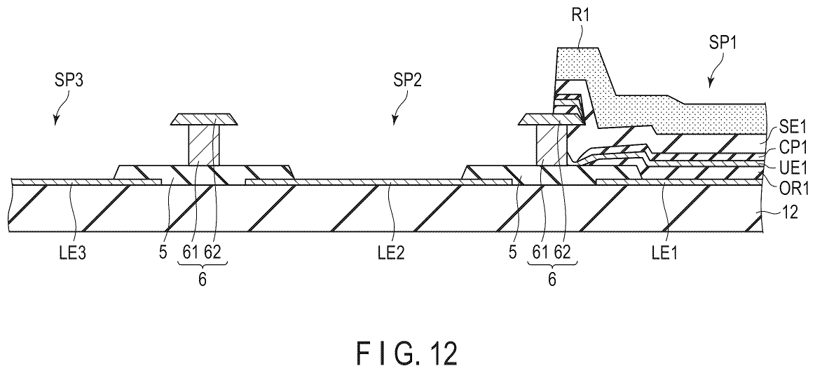

Subsequently, as shown in FIG. 12, the sealing layer SE1, cap layer CP1, upper electrode UE1 and organic layer OR1 exposed from the resist R1 are removed in series by performing etching using the resist R1 as a mask. In this manner, the lower electrode LE2 of subpixel SP2 and the lower electrode LE3 of subpixel SP3 are exposed.

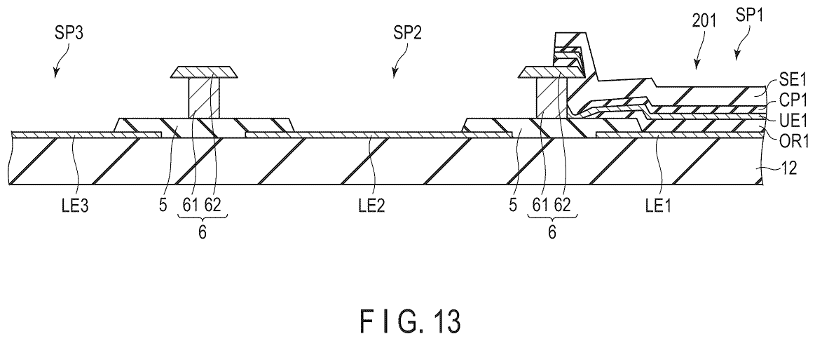

Subsequently, as shown in FIG. 13, the resist R1 is removed. By this process, the display element 201 is formed in subpixel SP1.

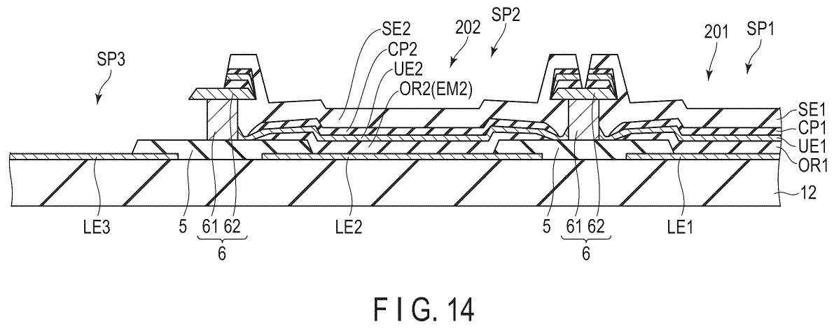

Subsequently, as shown in FIG. 14, the display element 202 is formed. The procedure of forming the display element 202 is similar to that of forming the display element 201. Specifically, the organic layer OR2 including the light emitting layer EM2, the upper electrode UE2, the cap layer CP2 and the sealing layer SE2 are formed in order on the lower electrode LE2. Subsequently, a resist is formed on the sealing layer SE2. The sealing layer SE2, the cap layer CP2, the upper electrode UE2 and the organic layer OR2 are patterned in series by performing etching using the resist as a mask. After this patterning, the resist is removed. In this manner, the display element 202 is formed in subpixel SP2, and the lower electrode LE3 of subpixel SP3 is exposed.

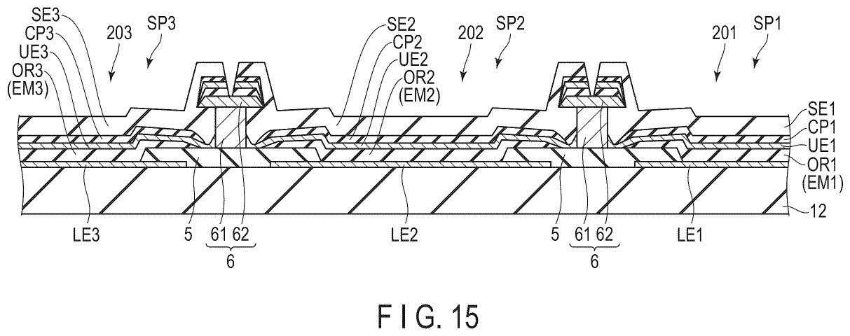

Subsequently, as shown in FIG. 15, the display element 203 is formed. The procedure of forming the display element 203 is similar to that of forming the display element 201. Specifically, the organic layer OR3 including the light emitting layer EM3, the upper electrode UE3, the cap layer CP3 and the sealing layer SE3 are formed in order on the lower electrode LE3. Subsequently, a resist is formed on the sealing layer SE3. The sealing layer SE3, the cap layer CP3, the upper electrode UE3 and the organic layer OR3 are patterned in series by performing etching using the resist as a mask. After this patterning, the resist is removed. By this process, the display element 203 is formed in subpixel SP3.

Subsequently, the resin layer 13, sealing layer 14 and resin layer 15 shown in FIG. 3 are formed in order. By this process, the display device DSP is completed. In the manufacturing process described above, this specification assumes a case where the display element 201 is formed firstly, and the display element 202 is formed secondly, and the display element 203 is formed lastly. However, the formation order of the display elements 201, 202 and 203 is not limited to this example.

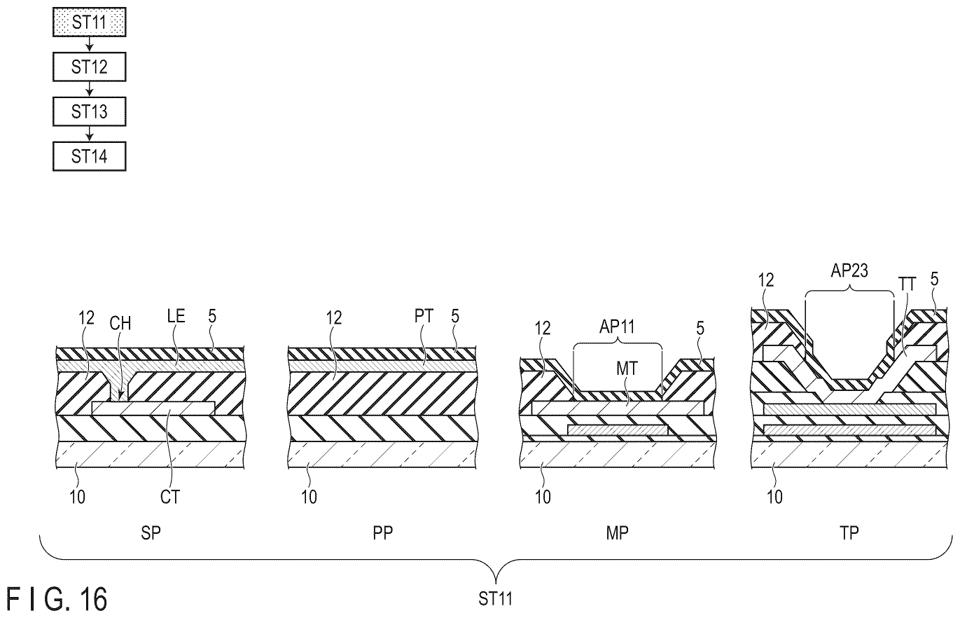

Now, this specification explains a first manufacturing method for manufacturing the feed portion PP, the mounting portion MP and the inspection portion TP through the process of forming the inorganic insulating layer 5 shown in FIG. 7 to the process of forming the apertures AP1, AP2 and AP3 shown in FIG. 9 in the manufacturing process described above. Each of FIG. 16 to FIG. 24 referred to in the following explanation shows the sections of the main parts of a subpixel SP, the feed portion PP, the mounting portion MP and the inspection portion TP. It should be noted that the subpixel SP corresponds to one of subpixels SP1, SP2 and SP3 described above.

First, the inorganic insulating layer 5 is formed in step ST11 shown in FIG. 16. The process shown in FIG. 16 is the same as the process of forming the inorganic insulating layer 5 shown in FIG. 7. Specifically, in this process, the inorganic insulating layer 5 which covers the feed terminal PT of the feed portion PP, the mounting terminal MT of the mounting portion MP and the inspection terminal TT of the inspection portion TP in the surrounding area in addition to the lower electrode LE of each subpixel SP located in the display area is formed. The inorganic insulating layer 5 is formed of, for example, silicon oxynitride.

The lower electrode LE corresponds to one of the lower electrodes LE1, LE2 and LE3 described above. The lower electrode LE is in contact with a connection terminal CT included in the pixel circuit through the contact hole CH formed in the organic insulating layer 12. The connection terminal CT is formed of the same material as the mounting terminal MT, etc.

In the mounting portion MP, the inorganic insulating layer 5 covers the organic insulating layer 12 and also covers the mounting terminal MT through the aperture AP11.

In the inspection portion TP, the inorganic insulating layer 5 covers the organic insulating layer 12 and also covers the inspection terminal TT through the aperture AP23.

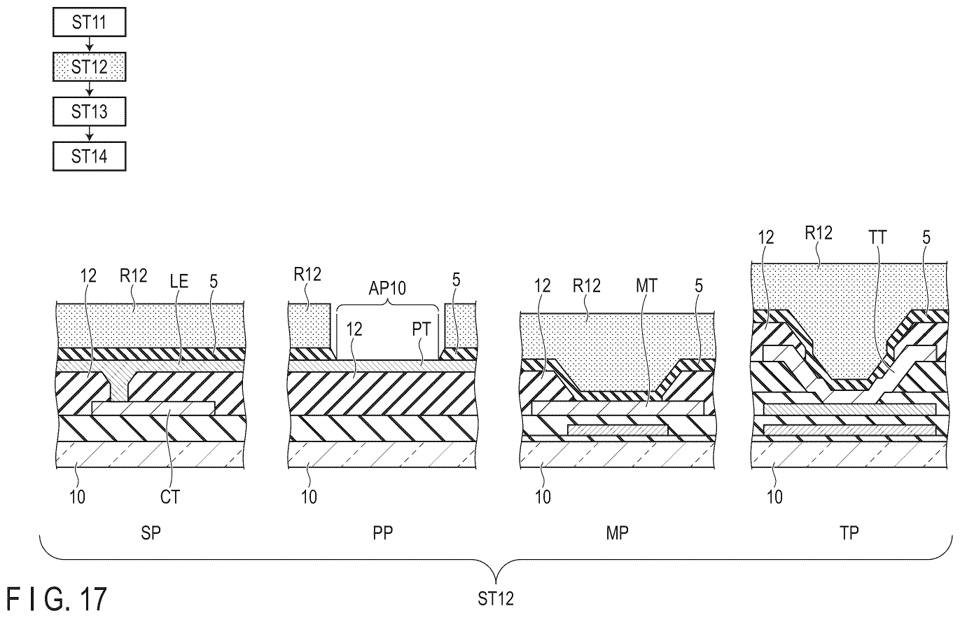

Subsequently, in step ST12 shown in FIG. 17, a resist R12 having a predetermined shape is formed on the inorganic insulating layer 5, and subsequently, etching is performed using the resist R12 as a mask, and thus, the aperture AP10 from which the feed terminal PT is exposed is formed in the inorganic insulating layer 5. In this process, the subpixel SP, the mounting portion MP and the inspection portion TP are covered with the resist R12. The process shown in

FIG. 17 is performed before the process of forming the partition 6 shown in FIG. 8. Subsequently, the resist R12 is removed.

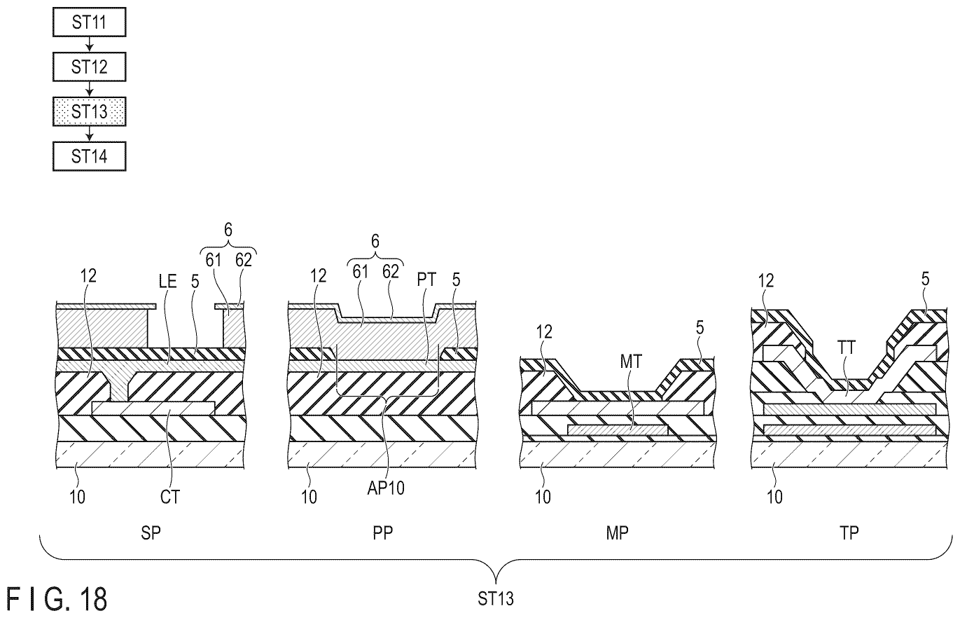

Subsequently, the partition 6 is formed in step ST13 shown in FIG. 18. The process shown in FIG. 18 is the same as the process of forming the partition 6 shown in FIG. 8. Specifically, the second layer is formed on the first layer after forming the first layer including a conductive layer on the inorganic insulating layer 5. Subsequently, the second layer and the first layer are patterned in order. By this process, the partition 6 is formed in the subpixel SP, and further, the partition 6 which is in contact with the feed portion PT through the aperture AP10 is formed in the feed portion PP. In the mounting portion MP and the inspection portion TP, the first layer and second layer for forming the partition 6 are removed, and the inorganic insulating layer 5 is exposed.

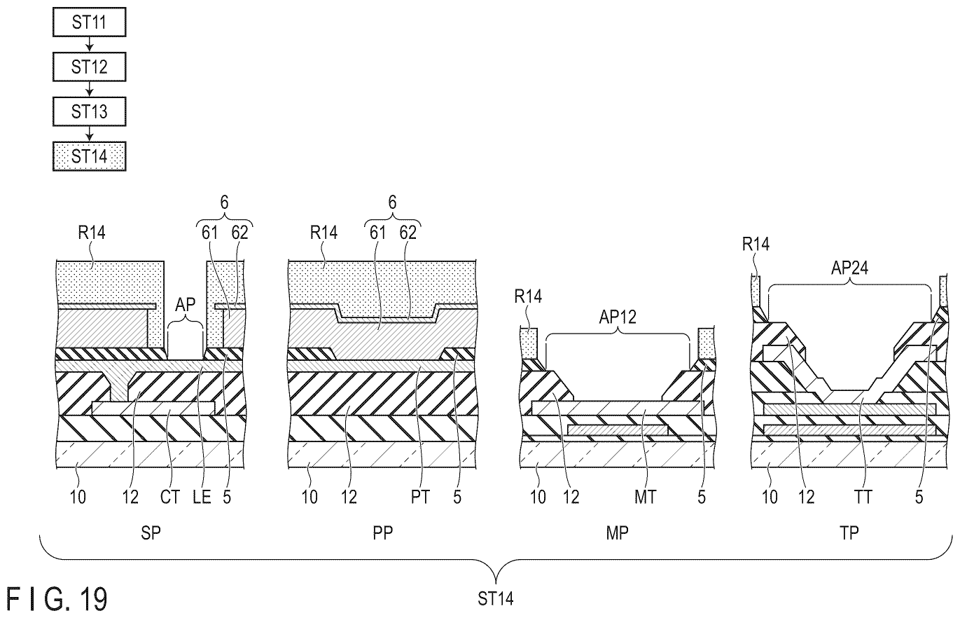

Subsequently, in step ST14 shown in FIG. 19, a resist R14 having a predetermined shape is formed on the inorganic insulating layer 5 and the partition 6, and subsequently, etching is performed using the resist R14 as a mask, and thus, the aperture AP from which the lower electrode LE is exposed is formed in the inorganic insulating layer 5.

In this process, the feed portion PP is covered with the resist R14.

Further, in this process, the aperture AP12 from which the mounting terminal MT is exposed is formed in the inorganic insulating layer 5 in the mounting portion MP.

Moreover, in this process, the aperture AP24 from which the inspection terminal TT is exposed is formed in the inorganic insulating layer 5 in the inspection portion TP.

The process shown in FIG. 19 is the same as the process shown in FIG. 9. Subsequently, the resist R14 is removed.

As explained above, the aperture AP12 from which the mounting terminal MT is exposed and the aperture AP24 from which the inspection terminal TT is exposed are formed at the same time in the process of forming the aperture AP from which the lower electrode LE is exposed. Thus, compared with a case where the aperture AP, the aperture AP12 and the aperture AP24 are separately formed, the manufacturing process can be simplified, and the manufacturing yield can be improved.

In the process of forming the partition 6, all of the lower electrode LE, the mounting terminal MT and the inspection terminal TT are covered with the inorganic insulating layer 5. Therefore, the lower electrode LE, the mounting terminal MT or the inspection terminal TT is not exposed to an etching gas or etching liquid for forming the lower portion 61 or upper portion 62 of the partition 6. Thus, they are not damaged in the process of forming the partition. In this manner, the reduction in reliability can be prevented.

In the first manufacturing method described above, the resist R12 corresponds to a first resist, and the resist R14 corresponds to a second resist.

Now, this specification explains a second manufacturing method for manufacturing the feed portion PP, the mounting portion MP and the inspection portion TP.

In the second manufacturing method, first, step ST11 explained with reference to FIG. 16 is performed. Subsequently, step ST12 explained with reference to FIG. 17 is performed. Subsequently, step ST13 explained with reference to FIG. 18 is performed. Explanation of step ST11 and step ST12 is omitted.

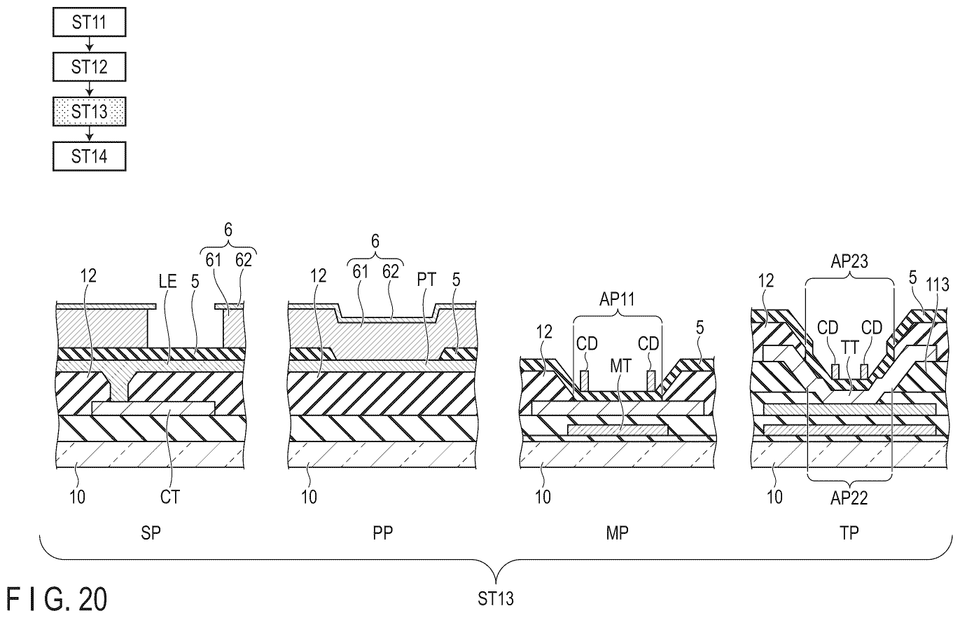

FIG. 20 shows a state in which a material CD for forming the partition 6 partly remains in the mounting portion MP and the inspection portion TP in step ST13 shown in FIG. 18. For example, a large step is formed in the aperture AP11 of the organic insulating layer 12 in the mounting portion MP. In the inspection portion TP, a larger step is formed in the aperture AP22 of the organic insulating layer 113 and the aperture AP23 of the organic insulating layer 12. For this reason, the first layer or second layer for forming the partition 6 may not be completely removed. If the etching condition is changed to completely remove the first and second layers located in the area where a large step is formed as described above, the partition 6 in the display area may not be formed into the desired overhang shape.

To solve this problem, in the second manufacturing method, the following process is performed after step ST13.

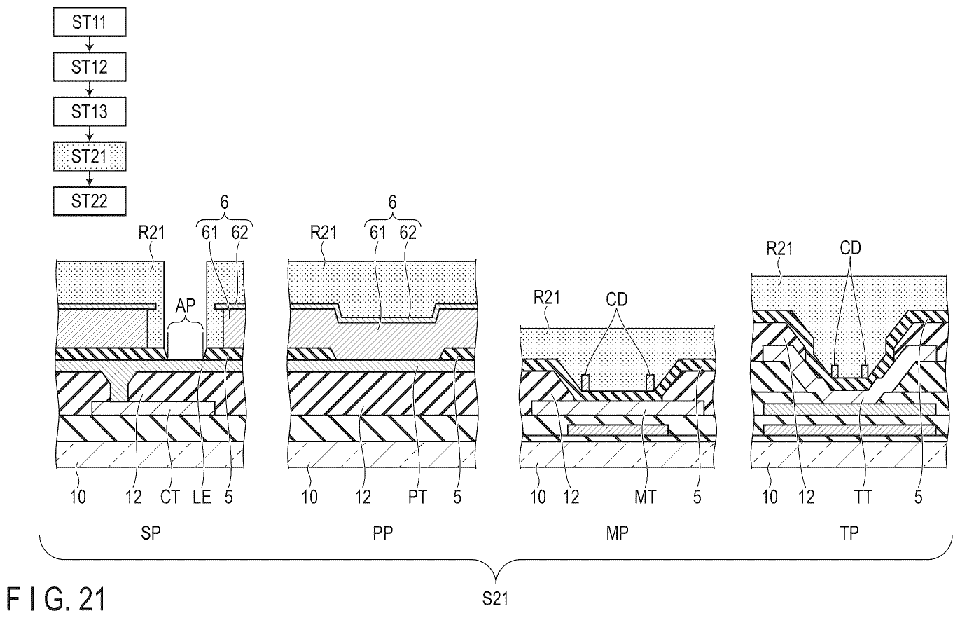

First, in step ST21 shown in FIG. 21, a resist R21 having a predetermined shape is formed on the inorganic insulating layer 5 and the partition 6, and subsequently, etching is performed using the resist R21 as a mask, and thus, the aperture AP from which the lower electrode LE is exposed is formed in the inorganic insulating layer 5.

In this process, the feed portion PP, the mounting portion MP and the inspection portion TP are covered with the resist R21.

The process shown in FIG. 21 is the same as the process shown in FIG. 9. Subsequently, the resist R21 is removed.

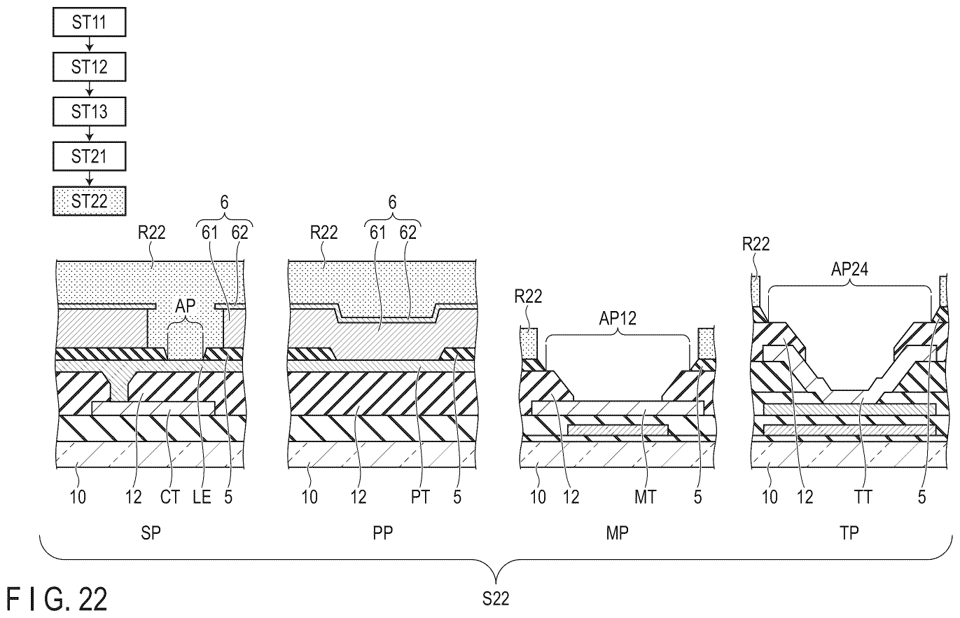

Subsequently, in step ST22 shown in FIG. 22, a resist R22 which covers the lower electrode LE exposed from the aperture AP and has a predetermined shape is formed on the inorganic insulating layer 5 and the partition 6. In the example shown in the figure, the resist R22 blocks the aperture AP of the subpixel SP, covers the partition 6 and is formed on the partition 6 of the feed portion PP. Subsequently, the aperture AP12 from which the mounting terminal MT is exposed is formed in the inorganic insulating layer 5 by performing etching using the resist R22 as a mask. At this time, the material (residue) CD of the partition 6 remaining in the mounting portion MP is also removed.

Further, in this process, the aperture AP24 from which the inspection terminal TT is exposed is formed in the inorganic insulating layer 5 in the inspection portion TP. At this time, the material (residue) CD of the partition 6 remaining in the inspection portion TP is also removed.

Subsequently, the resist R22 is removed.

As explained above, the residues of the mounting portion MP and the inspection portion TP can be assuredly removed without changing the etching condition for forming the partition 6 having the desired shape. Further, the mounting terminal MT and the inspection terminal TT are sufficiently exposed. Thus, defective connection with the signal sources and defective connection with the inspection probe can be prevented.

Moreover, the aperture AP of the subpixel SP and the partition 6 are covered with the resist R22 when the aperture AP12 from which the mounting terminal MT is exposed and the aperture AP24 from which the inspection terminal TT is exposed are formed. For this reason, the lower electrode LE or the partition 6 is not damaged in the formation process of the aperture AP12 and the aperture AP24. In this manner, the reduction in reliability can be prevented.

In the second manufacturing method described above, the resist R12 corresponds to the first resist, and the resist R21 corresponds to the second resist, and the resist R22 corresponds to a third resist.

Now, this specification explains a third manufacturing method for manufacturing the feed portion PP, the mounting portion MP and the inspection portion TP.

In the third manufacturing method, first, step ST11 explained with reference to FIG. 16 is performed. Subsequently, step ST12 explained with reference to FIG. 17 is performed. Subsequently, step ST13 explained with reference to FIG. 18 is performed. Explanation of step ST11 and step ST12 is omitted. In step ST13, it is assumed that the material CD for forming the partition 6 partly remains in the mounting portion MP and the inspection portion TP as shown in FIG. 20.

In the third manufacturing method, the following process is performed after step ST13.

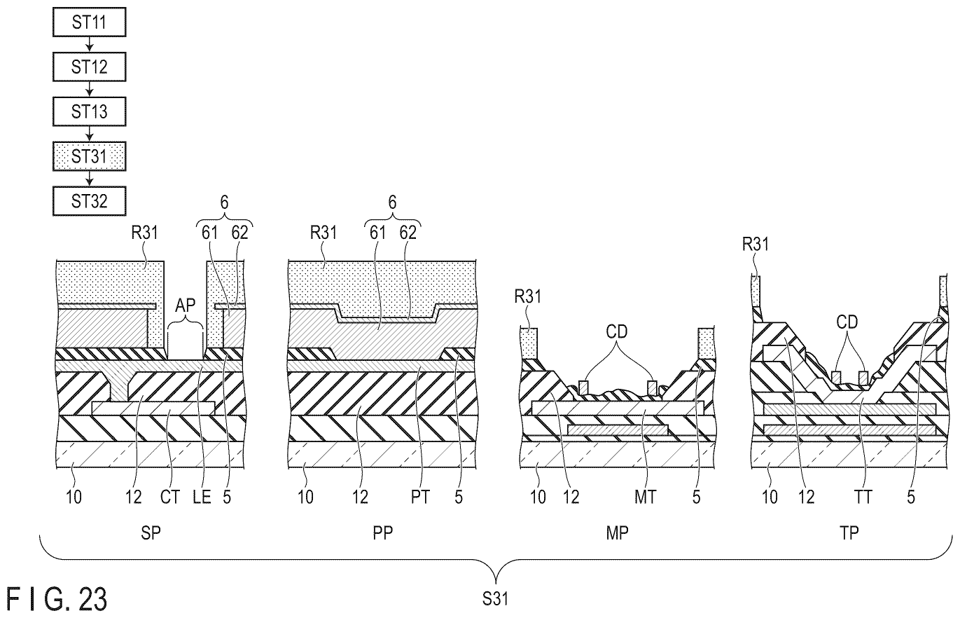

First, in step ST31 shown in FIG. 23, a resist R31 having a predetermined shape is formed on the inorganic insulating layer 5 and the partition 6, and subsequently, etching is performed using the resist R31 as a mask, and thus, the aperture AP from which the lower electrode LE is exposed is formed in the inorganic insulating layer 5.

In this process, part of the inorganic insulating layer 5 which overlaps the mounting terminal MT is also removed in the mounting portion MP. If the material CD remains in the mounting portion MP, the inorganic insulating layer 5 which overlaps the mounting terminal MT cannot be completely removed.

Further, in this process, part of the inorganic insulating layer 5 which overlaps the inspection terminal TT is also removed in the inspection portion TP. If the material CD remains in the inspection portion TP, the inorganic insulating layer 5 which overlaps the inspection terminal TT cannot be completely removed.

In this process, the feed portion PP is covered with the resist R31.

The process shown in FIG. 23 is the same as the process shown in FIG. 9. Subsequently, the resist R31 is removed.

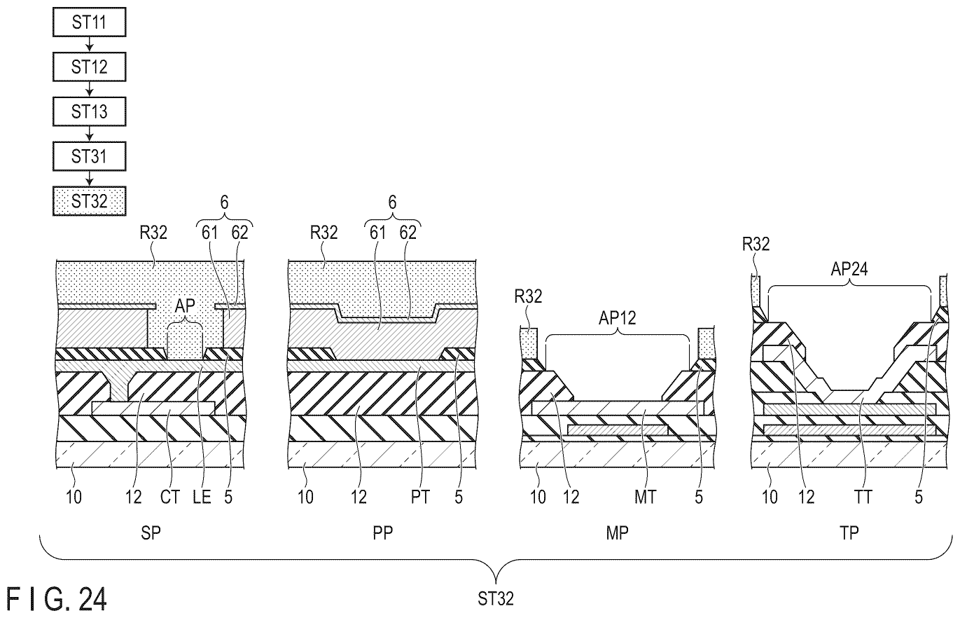

Subsequently, in step ST32 shown in FIG. 24, a resist R32 which covers the lower electrode LE exposed from the aperture AP and has a predetermined shape is formed on the inorganic insulating layer 5 and the partition 6. In the example shown in the figure, the resist R32 blocks the aperture AP of the subpixel SP, covers the partition 6 and is formed on the partition 6 of the feed portion PP. Subsequently, the aperture AP12 from which the mounting terminal MT is exposed is formed in the inorganic insulating layer 5 by performing etching using the resist R32 as a mask. At this time, the material CD remaining in the mounting portion MP is also removed.

Further, in this process, the aperture AP24 from which the inspection terminal TT is exposed is formed in the inorganic insulating layer 5 in the inspection portion TP. At this time, the material CD remaining in the inspection portion TP is also removed.

Subsequently, the resist R32 is removed.

In the third manufacturing method explained above, effects similar to those of the second manufacturing method described above are obtained.

In the third manufacturing method described above, the resist R12 corresponds to the first resist, and the resist R31 corresponds to the second resist, and the resist R32 corresponds to the third resist.

As explained above, the present embodiment can provide a display device in which the manufacturing yield can be improved and a manufacturing method thereof.

All of the display devices and manufacturing methods thereof that can be implemented by a person of ordinary skill in the art through arbitrary design changes to the display device and manufacturing method thereof described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A manufacturing method of a display device, comprising:
forming an inorganic insulating layer which covers a lower electrode located in a display area, a feed terminal located in a surrounding area outside the display area, and a mounting terminal for mounting a signal source;
forming a first aperture from which the feed terminal is exposed in the inorganic insulating layer by performing etching using a first resist formed on the inorganic insulating layer as a mask;
forming a partition comprising a conductive lower portion which is located on the inorganic insulating layer in the display area and is in contact with the feed terminal through the first aperture in the surrounding area, and an upper portion which is located on the lower portion and protrudes from a side surface of the lower portion, after removing the first resist;
forming a second aperture from which the lower electrode is exposed in the inorganic insulating layer by performing etching using a second resist formed on the inorganic insulating layer and the partition as a mask;
forming an organic layer which is in contact with the lower electrode through the second aperture by depositing a first material using the partition as a mask, after removing the second resist; and
forming an upper electrode which covers the organic layer and is in contact with the lower portion of the partition by depositing a second material using the partition as a mask.

2. The manufacturing method of claim 1, wherein
in the process of performing etching using the second resist as the mask, further, a third aperture from which the mounting terminal is exposed is formed in the inorganic insulating layer.

3. The manufacturing method of claim 2, wherein
the inorganic insulating layer covers an inspection terminal for connecting an inspection probe, and
in the process of performing etching using the second resist as the mask, further, a fourth aperture from which the inspection terminal is exposed is formed in the inorganic insulating layer.

4. The manufacturing method of claim 1, wherein
after the second resist is removed, and before the organic layer is formed, further,
a third aperture from which the mounting terminal is exposed is formed in the inorganic insulating layer by performing etching using a third resist which covers the lower electrode exposed from the second aperture and which is formed on the inorganic insulating layer and the partition as a mask.

5. The manufacturing method of claim 4, wherein
the inorganic insulating layer covers an inspection terminal for connecting an inspection probe, and
in the process of performing etching using the third resist as the mask, further, a fourth aperture from which the inspection terminal is exposed is formed in the inorganic insulating layer.

6. The manufacturing method of claim 1, wherein
in the process of performing etching using the second resist as the mask, further, part of the inorganic insulating layer overlapping the mounting terminal is removed, and
after the second resist is removed, and before the organic layer is formed, further,
a third aperture from which the mounting terminal is exposed is formed in the inorganic insulating layer by performing etching using a third resist which covers the lower electrode exposed from the second aperture and which is formed on the inorganic insulating layer and the partition as a mask.

7. The manufacturing method of claim 6, wherein
the inorganic insulating layer covers an inspection terminal for connecting an inspection probe,
in the process of performing etching using the second resist as the mask, further, part of the inorganic insulating layer overlapping the inspection terminal is removed, and
in the process of performing etching using the third resist as the mask, further, a fourth aperture from which the inspection terminal is exposed is formed in the inorganic insulating layer.

8. The manufacturing method of claim 1, wherein
the inorganic insulating layer is formed of silicon oxynitride (SiON).

9. A display device comprising:
a substrate;
an organic insulating layer provided over a display area and a surrounding area outside the display area above the substrate;
a lower electrode provided on the organic insulating layer in the display area;
a feed terminal provided on the organic insulating layer in the surrounding area;
a mounting terminal exposed from a first through hole of the organic insulating layer in the surrounding area;
an inorganic insulating layer provided over the display area and the surrounding area on the organic insulating layer, and comprising a first aperture from which the feed terminal is exposed, a second aperture from which the lower electrode is exposed, and a third aperture from which the mounting terminal is exposed;
a partition comprising a conductive lower portion which is provided on the inorganic insulating layer and is in contact with the feed terminal through the first aperture, and an upper portion which is provided on the lower portion and protrudes from a side surface of the lower portion;
an organic layer which is in contact with the lower electrode through the second aperture; and
an upper electrode which covers the organic layer and is in contact with the lower portion of the partition.

10. The display device of claim 9, further comprising an inspection terminal exposed from a second through hole of the organic insulating layer in the surrounding area, wherein
the inorganic insulating layer comprises a fourth aperture from which the inspection terminal is exposed.

11. The display device of claim 10, wherein
the lower electrode and the feed terminal are formed of a same material, and
the mounting terminal and the inspection terminal are formed of a same material which is different from the lower electrode.

12. The display device of claim 9, wherein
the inorganic insulating layer is formed of silicon oxynitride (SiON).

13. The display device of claim 9, wherein
the third aperture overlaps the first through hole, and the organic insulating layer surrounding the first through hole is exposed from the third aperture.

14. The display device of claim 10, wherein
the fourth aperture overlaps the second through hole, and the organic insulating layer surrounding the second through hole is exposed from the fourth aperture.

15. The display device of claim 9, further comprising:
a cap layer provided on the upper electrode; and
a sealing layer provided on the cap layer and formed of an inorganic insulating material.

16. A display device comprising:
a substrate;
an organic insulating layer provided over a display area and a surrounding area outside the display area above the substrate;
a lower electrode provided on the organic insulating layer in the display area;
a feed terminal provided on the organic insulating layer in the surrounding area;
an inorganic insulating layer provided over the display area and the surrounding area on the organic insulating layer and comprising a first aperture from which the feed terminal is exposed and a second aperture from which the lower electrode is exposed;
a partition comprising a conductive lower portion which is provided on the inorganic insulating layer and is in contact with the feed terminal through the first aperture and an upper portion which is provided on the lower portion and protrudes from a side surface of the lower portion;
an organic layer which is in contact with the lower electrode through the second aperture; and
an upper electrode which is provided on the organic layer and is in contact with the lower portion of the partition.

17. The display device of claim 16, wherein
the lower electrode and the feed terminal are formed of a same material.

18. The display device of claim 16, wherein
each of the lower electrode and the feed terminal is a multilayer body including a transparent electrode and a metal electrode.

19. The display device of claim 16, wherein
the feed terminal is a terminal for supplying common voltage to the upper electrode.

20. The display device of claim 16, further comprising:
a cap layer provided on the upper electrode; and
a sealing layer provided on the cap layer and formed of an inorganic insulating material.
